(19) United States
(12) Patent Application Publication
(10) Pub. No.: US 2006/0281326 A1
(43) Pub. Date: Dec. 14, 2006

(54) Washing apparatus, washing stystem, and washing method

(75) Inventors: Hiroki Ose, Fukushima (JP); Shuji Yokota, Fukushima (JP)

Correspondence Address: MCGLEW & TUTTLE, PC, P.O. BOX 9227, SCARBOROUGH STATION, SCARBOROUGH, NY, 10510-9227, US

(73) Assignee: Shin-etsu Handotai Co., Ltd.

(21) Appl. No.: 10/554,265

(22) PCT Filed: Apr. 6, 2004
(86) PCT No.: PCT/JP04/04940

§ 371 Date: Oct. 25, 2005

(30) Foreign Application Priority Data
May 9, 2003 (JP) 2003-131386

(51) Int. Cl. H01L 21/00; H01L 21/302

(52) U.S. Cl. 438/745; 438/43

(57) ABSTRACT

The present invention provides a cleaning apparatus, a cleaning system and a cleaning method for a member used in the semiconductor field, excellent in cleaning capability and good in operation efficiency. The present invention is directed to a cleaning apparatus for cleaning the member used in the semiconductor field, which comprises: one nozzle or plural nozzles; and a jet mechanism for jetting a mist-like cleaning liquid (L1) with a high pressure from the one nozzle or the plural nozzles (52a) to the member (T) to be cleaned. The present invention is also directed to a cleaning system (30) for cleaning members used in the semiconductor field, which comprises: a loader section (40) for setting a member to be cleaned; an unloader section (70) for collecting the members; and a transport stage (80) for continuously transporting the member from the loader section to the unloader section, wherein a cleaning section (50) for cleaning the member with a mist-like cleaning liquid is provided on the transport stage, and the member is transported by the transport stage and is also cleaned in the cleaning section.

### TECHNICAL FIELD

The present invention relates to a cleaning technique for a member (a member to be cleaned) used in the semiconductor field, and in particular, to a cleaning apparatus for a wafer accommodating container used in a field in which a cleanliness level is severely demanded by a user such as, especially, a wafer maker or a semiconductor maker (or a device maker) and for a wafer carrier employed between processes, to a cleaning system excellent in cleaning effect and good in operability and to a cleaning method for cleaning the member to be cleaned.

### BACKGROUND ART

In a progress in recent miniaturization of devices accompanied with a higher level of integration in semiconductor circuits such as semiconductor devices, a quality requirement for a wafer serving as a substrate therefor has been progressively enhanced. More of attention has been directed to contamination due to dust on the micron order or the submicron order in particle size as a problem. Such dust is generally called particles. In the state of the art today, fine particles that are conventionally not problematic must be removed. Therefore, in order to prevent generation of dust and contamination due to attached dust, factors activating a generation source are indispensably removed.

A so-called wafer carrier or the like for handling wafers used in fabrication process for semiconductor devices or wafers has to be always maintained in a clean state because of direct contact with wafers. In a case where wafers mirror-polished in a wafer fabrication process are accommodated in a container and the wafers are shipped to a company such as a device maker as well, cleanliness of the container is an important issue.

Therefore, in a wafer maker and a semiconductor maker (a device maker), severe control of cleanliness is currently imposed on wafer carriers, accommodation containers or the like for accommodating semiconductor wafers used in the semiconductor field, and a cleaning technique for the members used in the semiconductor field has become important more and more.

There has been known a wafer accommodating container with, for example, a structure as shown in FIGS. 17 to 19. In the figures, a wafer accommodating container 12 is constituted of: a container body (or a lower box) 14 for accommodating wafers W and a cover 16 for closing a top opening of the container proper 14. Substrates accommodating cassette or an inner cassette 18 for accommodating many of wafers are, as shown in FIG. 19, placed in the container body 14. Incidentally, a reference 20 designates a packing (or a gasket) attached along a periphery of the top opening of the container body 14 and a reference 22 designates a substrate presser (or a retainer) attached on the top side of the substrate accommodating cassette.

### DISCLOSURE OF THE INVENTION

Conventionally, a method as disclosed in, for example, JP-A No. 4-309225 and the like has been generally used in cleaning such a member used in the semiconductor field, especially an irregularly shaped member such as a wafer carrier or a wafer accommodating container. That is, a member such as a carrier to be cleaned is dipped and cleaned in a cleaning bath containing a chemical solution or the like. A system is especially proposed in JP-A No. 4-309225 in which the above process is automated and which are constituted of a first stocker for accommodating a carrier before cleaning; a brush cleaning bath, a chemical solution bath, a pure water bath and a drying vessel for cleaning the carrier; a second stocker for accommodating a carrier after cleaning; and a transport mechanism for transporting the carrier.

In a case where a carrier cannot be held directly or transported, the carrier or an accommodating container and constituents thereof are put in a vessel such as a basket and, as described above, are dipped and cleaned in a cleaning bath containing a cleaning liquid (pure water or a chemical solution). Incidentally, in cleaning, various techniques are applied: such as a brush cleaning, bubbling in a cleaning bath and cleaning using a supersonic wave. Moreover, an organic solvent is in some case used for cleaning.

A cleaning apparatus and a cleaning method conventionally adopted, which are described above, have had various problems in aspects of an operation efficiency, a quality level and an apparatus cost.

For example, in brush cleaning, tips of bristles of a brush are difficult to intrude into grooves into which wafers are inserted in a wafer accommodating container or the like, which makes it hard to clean the grooves and moreover, since depths of grooves are deepened in company with increase in diameter of a wafer, such a problem has revealed in a more conspicuous level. Therefore, cleaning has been more and more difficult in company with increase in wafer diameter. Besides, automation has also been difficult in brush cleaning, because the wafers have complex shapes, various sizes and differences in their shapes.

If brush cleaning was automated, the automated brush cleaning, in many cases, could be used only for a special shape with lack in general versatility, causing a high cost, so that there are some cases where manual processing has been better in not only cost but operation efficiency. In such a way, a problem has occurred in automatic cleaning for members to be cleaned each in an irregular shape.

Especially, in an apparatus of a type in which a member is dipped and cleaned, a problem has occurred that particles are accumulated in a cleaning solution, for example, in a case where plural carriers are cleaned in the same bath and the particles attach to carriers dipped after the plural carriers are cleaned therein (reattachment of particles), which degrades a cleaning capability.

Other cleaning apparatuses are disclosed in JP-A Nos. 1-199431 and 10-34094, in which a cleaning liquid (a chemical solution, pure water or the like) is sprayed to a member with a nozzle to thereby clean the member.

The apparatus in such a construction has less of a problem such as reattachment of particles, but has a fault in processing capability and is complex in structural construction, resulting in a highly expensive apparatus. It is an object of the present invention to provide a cleaning apparatus, a cleaning system and a cleaning method for a member used in the semiconductor field, excellent in cleaning capability and good in operation efficiency.

In order to solve the problems, a cleaning apparatus of the present invention is directed to a cleaning apparatus for cleaning a member used in the semiconductor field, which comprises: one nozzle or plural nozzles; and a jet mechanism for jetting a mist-like cleaning liquid with a high pressure from the one nozzle or the plural nozzles to the member to be cleaned.

A container or the like requiring a high cleanliness level as used in the semiconductor field is cleaned with a cleaning solution jetted in such a mist state, thereby enabling particles each very small in size or the like to be removed. Especially, in the cleaning apparatus of the present invention, the member is preferably cleaned with the nozzles disposed in directions upward and downward.

A particle size of the jetted mist-like cleaning liquid in the cleaning apparatus of the present invention is preferably 100 μm or less. A size of the waterdrop in a conventional shower method is on the order in the range of from about 0.5 to about 1.0 mm, while in the present invention, jetted fine mist has a particle size of the order in the range of from 10 to 100 μm. Since the mist-like cleaning liquid at such a fine mist level is jetted to the member to be cleaned, very small size particles attached to the member to be cleaned can be removed. It is thought that the advantages come from effects that very small size droplets intrude into details, number of particles is increased by down sizing droplets to result in increased cleaning number of times (a chemical solution acts on the same site many times) and residual water decreases because of decrease in actual water usage.

The mist-like cleaning liquid is preferably jetted in a state where a gas is mixed into the cleaning liquid in a liquid state. By making the mist-like cleaning liquid with such a method, the mist-like cleaning liquid with particle sizes as described above can be effectively produced.

Besides, by supplying a pressurized gas, a jet rate of droplets is increased and physical removal of foreign matters (a sweeping-out effect) is improved, so that there can be removed particles including large size to small size. A jet pressure of the mist-like cleaning liquid on this occasion is preferably on the order of 0.3 MPa (on the order in the range of from 0.2 to 0.4 MPa).

The cleaning liquid to be jetted uses pure water and various kinds of chemical solutions. Especially, an accommodating container for accommodating semiconductor wafers is preferably cleaned with pure water to which surfactant is added.

Then, description will be given of a cleaning system of the present invention. The cleaning system of the present invention is a cleaning system for cleaning members used in the semiconductor field comprises: a loader section for setting the member to be cleaned; an unloader section for collecting the member; and a transport stage for continuously transporting the member from the loader section to the unloader section, wherein a cleaning section for cleaning the member with a mist-like cleaning liquid is provided on the transport stage. A cleaning apparatus in the cleaning section is preferably, for example, a cleaning apparatus with a construction of the present invention in which a cleaning liquid is jetted in a mist state under a high pressure.

It is preferable that the cleaning section has an outer wall in the shape of a tunnel and a transport stage continuously transporting the member to be cleaned from the loader section to the unloader section. The transport stage is preferably a conveyor type transport apparatus using a long narrow belt of a ring type. With such a construction adopted, a member to be cleaned can be continuously cleaned. Besides, a mist-like cleaning liquid can also be supplied with ease in a direction from below the member to be cleaned through clearances of the conveyor.

Incidentally, the mist-like cleaning liquid may be supplied from a side (from the left or right side) without limiting to directions upward and downward. However, supply in the directions upward and downward has a sufficient cleaning effect.

An air curtain is preferably provided between the loader section and the cleaning section of the cleaning system of the present invention. With such a construction adopted, waterdrops generated in the cleaning section can be prevented from going outside of the cleaning system.

Incidentally, it is allowed to install plural cleaning sections for cleaning the members with a mist-like cleaning liquid. Effective cleaning is assured if the plural cleaning sections include at least a precleaning section with pure water, a cleaning section with a chemical solution, and a rinse section.

In the construction of the plural cleaning sections, water curtains are provided after the cleaning section, between the precleaning section and the chemical solution cleaning section, and between a chemical solution cleaning section and the rinse section, respectively. With such a construction adopted, the cleaning sections are clearly defined, and hence it is prevented that droplets are mixed, especially droplets of the chemical solution cleaning section are mixed into the precleaning section or into the rinse section. Besides, while very small waterdrops are attached to the member to be cleaned, the member passes through the water curtain to thereby grow the very small waterdrops to a large size waterdrop and to facilitate the waterdrops to be removed.

Incidentally, for the cleaning liquid (pure water) to be supplied in the precleaning section, the cleaning liquid (pure water) used in the rinse section may be preferably used according to a circulation system. With such recycling applied, pure water or the like is effectively used, resulting in decrease in cost.

Incidentally, a drying section for removing liquid attached to the member to be cleaned by air may be installed after the member passes through the cleaning section, which is not necessarily required as a constituent of the cleaning system of the present invention.

A cleaning method of the present invention, which is a cleaning method cleaning a member used in the semiconductor field, wherein a cleaning liquid with a small mist particle size is blown to a member to be cleaned under a high pressure to thereby clean the member.

For example, the member to be cleaned can be a wafer accommodating container for accommodating semiconductor wafers. While such a container is in a complex shape, even the container can also be cleaned by means of the cleaning method of the present invention.

Especially, according to the method of the present invention, a particle with a small size with the size of 0.5 μm or less attached to the member to be cleaned can be effectively removed. The method of the present invention can remove especially small size particles and effectively particles with 0.5 μm or less.

Cleaning conditions and others in the method of the present invention may be properly set to the optimal conditions, while in the method of the present invention, effective cleaning is ensured if the particle size of the mist-like cleaning liquid with the small particle size is 100 μm or less and the cleaning liquid is jetted under a pressure of the order of 0.3 MPa (of the order in the range of from 0.2 to 0.4 MPa).

### BRIEF DESCRIPTION OF THE DRAWINGS

FIG. 1 is a schematic side view showing the entire structure of a cleaning system of the present invention.

FIG. 2 is a schematic side view showing a loader section in the cleaning system of the present invention.

FIG. 3 is a schematic plan view showing the loader section in the cleaning system of the present invention.

FIG. 4 is a schematic front view showing the loader section in the cleaning system of the present invention.

FIG. 5 is a schematic side view showing a precleaning section in the cleaning system of the present invention.

FIG. 6 is a schematic front view showing the precleaning section in the cleaning system of the present invention.

FIG. 7 is a schematic side view showing a chemical solution cleaning section in the cleaning system of the present invention.

FIG. 8 is a schematic front view showing the chemical solution cleaning section in the cleaning system of the present invention.

FIG. 9 is a schematic side view showing a rinse section in the cleaning system of the present invention.

FIG. 10 is a schematic front view showing the rinse section in the cleaning system of the present invention.

FIG. 11 is a schematic side view showing a drying section in the cleaning system of the present invention.

FIG. 12 is a schematic front view showing the drying section in the cleaning system of the present invention.

FIG. 13 is a schematic side view showing an unloader section in the cleaning system of the present invention.

FIG. 14 is a schematic plan view showing the unloader section in the cleaning system of the present invention.

FIG. 15 is a schematic explanatory view showing a supply flow of cleaning liquids in the cleaning system of the present invention.

FIG. 16 is a schematic explanatory view showing a supply flow of air in the cleaning system of the present invention.

FIG. 17 is a perspective view showing an example of wafer accommodating container.

FIG. 18 is a perspective view showing the wafer accommodating container of FIG. 17 in a state where a cover thereof is opened upward.

FIG. 19 is an exploded perspective view of the wafer accommodating container of FIG. 17.

### BEST MODE FOR CARRYING OUT THE INVENTION

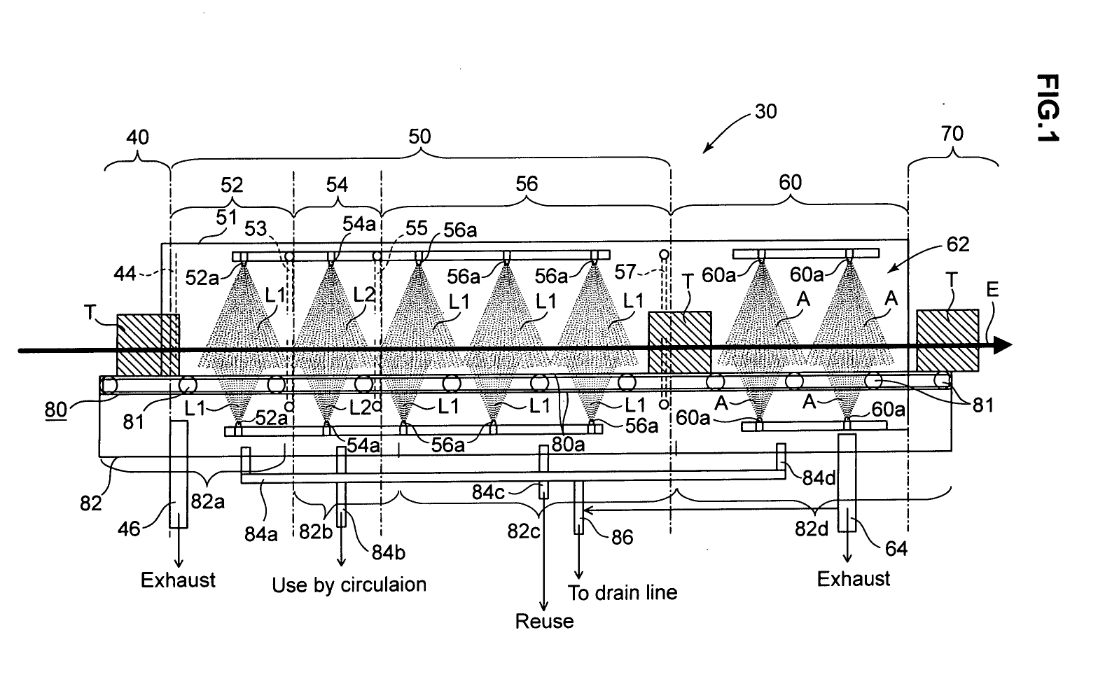

Description will be given of an embodiment of the present invention below with reference to FIGS. 1 to 16 of the accompanying drawing and it is needless to say that the examples shown in the figures are presented by way of illustration only and various modification or variations can be implemented as far as not departing from the technical concept of the present invention.

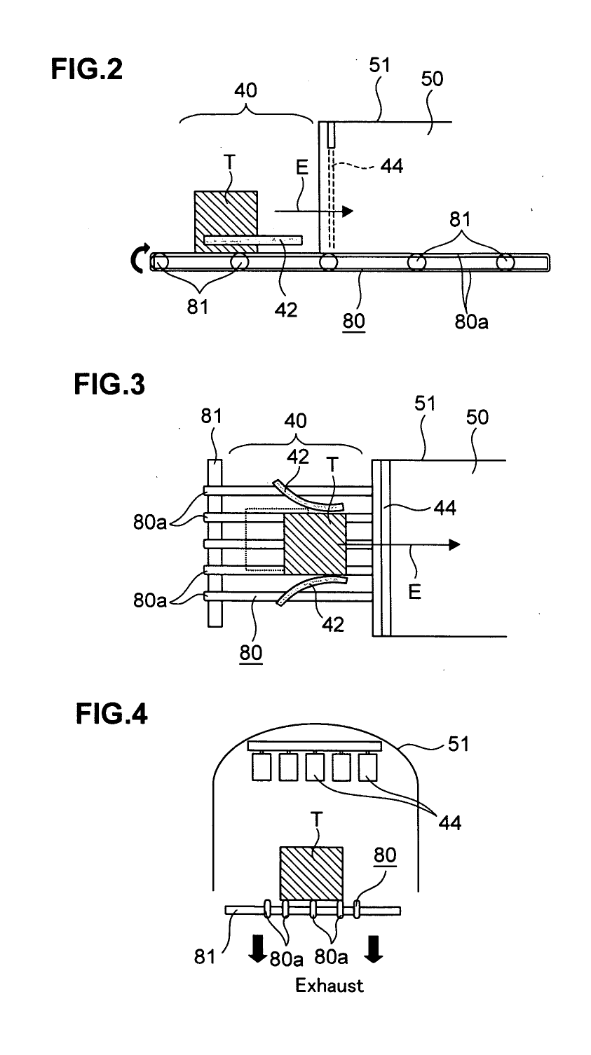

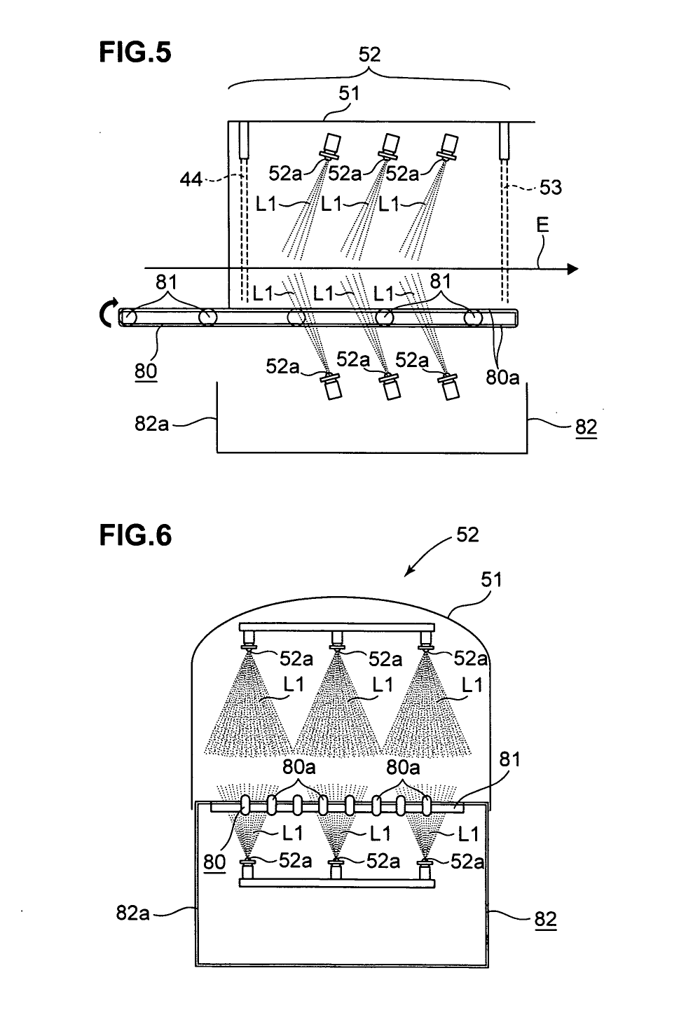

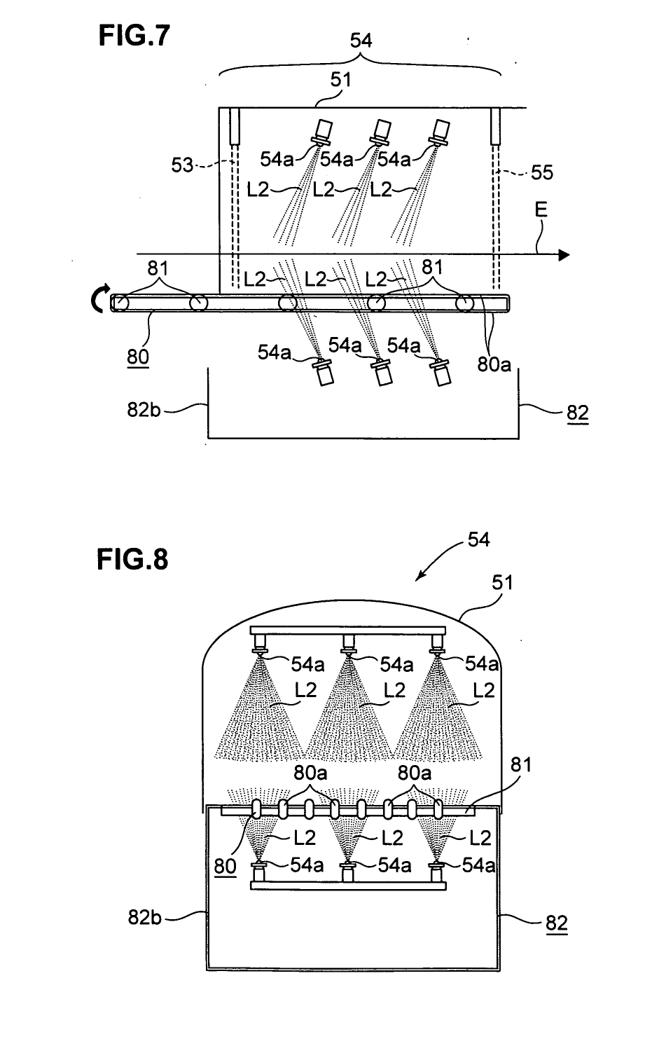

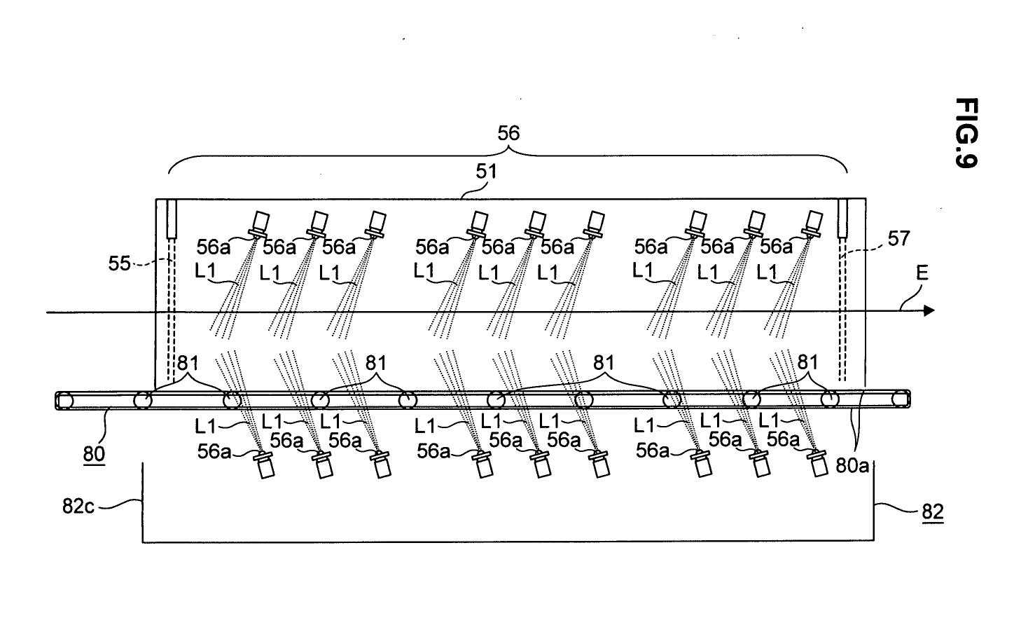

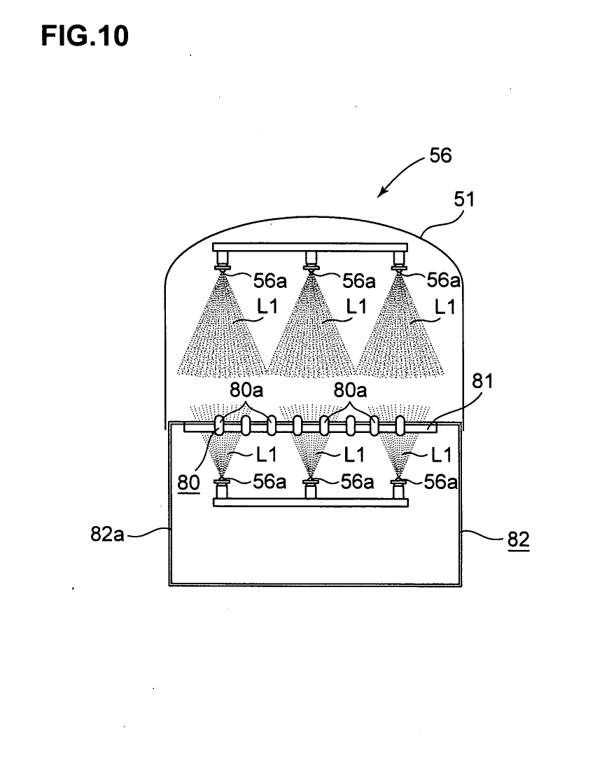

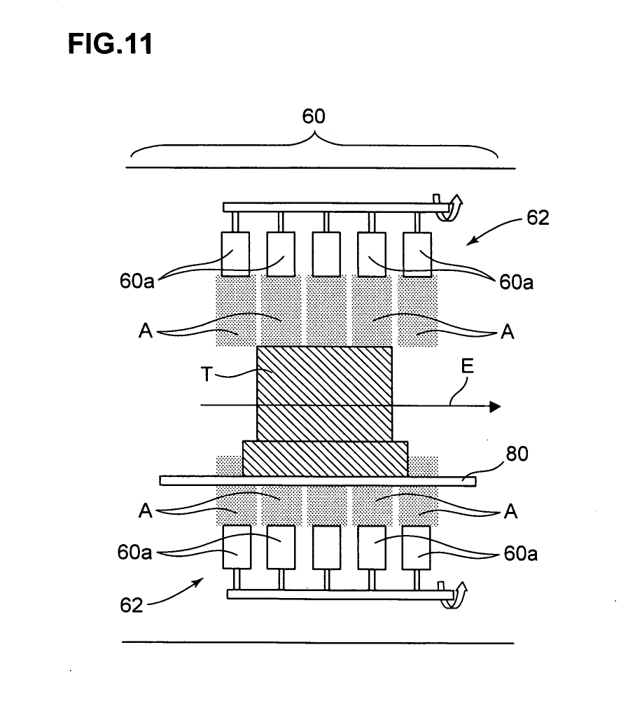

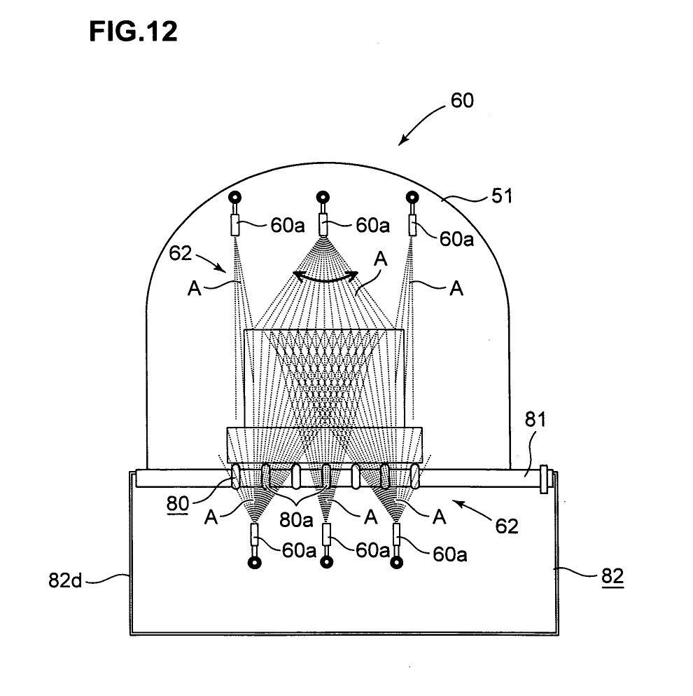

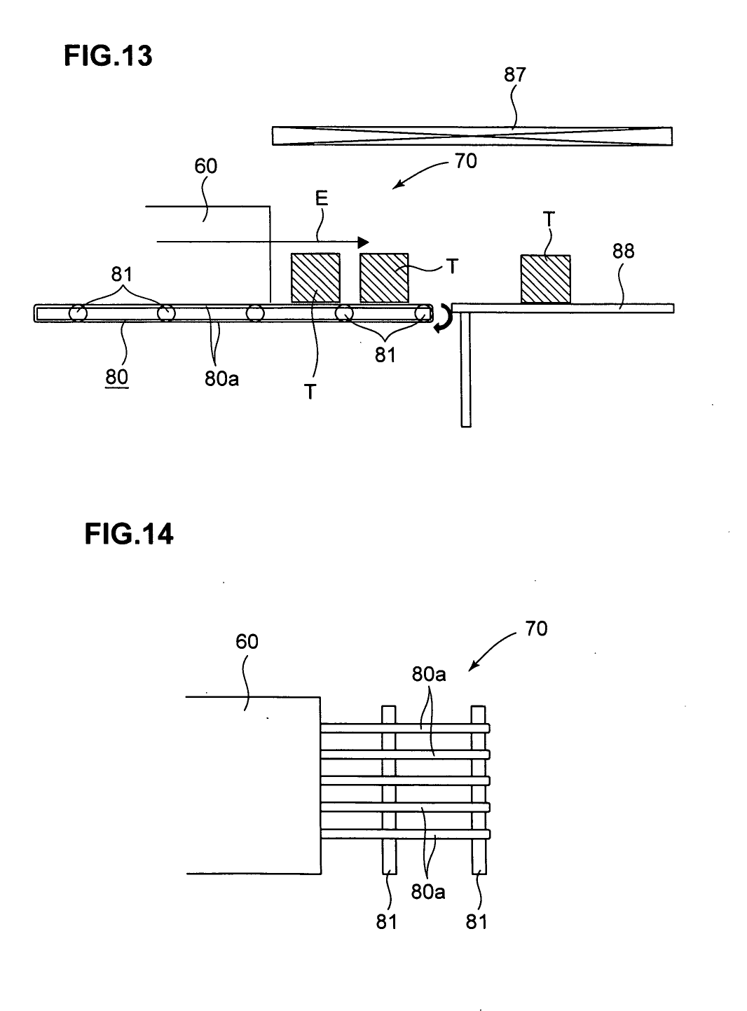

FIG. 1 is a schematic side view showing the entire structure of a cleaning system of the present invention. FIG. 2 is a schematic side view showing a loader section in the cleaning system of the present invention. FIG. 3 is a schematic plan view showing the loader section in the cleaning system of the present invention. FIG. 4 is a schematic front view showing the loader section in the cleaning system of the present invention. FIG. 5 is a schematic side view showing a precleaning section in the cleaning system of the present invention. FIG. 6 is a schematic front view showing the precleaning section in the cleaning system of the present invention. FIG. 7 is a schematic side view showing a chemical solution cleaning section in the cleaning system of the present invention. FIG. 8 is a schematic front view showing the chemical solution cleaning section in the cleaning system of the present invention. FIG. 9 is a schematic side view showing a rinse section in the cleaning system of the present invention. FIG. 10 is a schematic front view showing the rinse section in the cleaning system of the present invention. FIG. 11 is a schematic side view showing a drying section in the cleaning system of the present invention. FIG. 12 is a schematic front view showing the drying section in the cleaning system of the present invention. FIG. 13 is a schematic side view showing an unloader section in the cleaning system of the present invention. FIG. 14 is a schematic plan view showing the unloader section in the cleaning system of the present invention.

In FIG. 1, a reference 30 designates a cleaning system of the present invention, which cleans various kinds of members used in the semiconductor field where cleanliness is especially important, for example, members of a wafer accommodating container 12, wherein a member T to be cleaned is sent out from a loader section 40, cleaned in a cleaning section 50 and collected in an unloader section 70 (or discharged to the next step).

To be detailed, the cleaning system 30 of the present invention, as shown in FIG. 1, includes: the loader section 40 for mainly setting a member T to be cleaned; an unloader section 70 for collecting the cleaned member T to be cleaned; a transport stage 80 for transporting the member T to be cleaned to the unloader section 70 from the loader 40; and a cleaning section 50 for cleaning the member T to be cleaned with mist-like cleaning liquids L1 and L2 on the way of the transport stage 80. Incidentally, in FIG. 1, a reference 60 designates a drying section, which acts so as to drain off a liquid attached to the member T to be cleaned with air A after the member T to be cleaned passes through the cleaning section 50.

The cleaning section 50 has a tunnel-like outer wall 51 and the member T to be cleaned sent out from the loader 40 is cleaned while it passes through the tunnel-like outer wall 51. In this embodiment, there is used a transport means of a conveyor type as the transport stage 80 for transporting the member T to be cleaned continuously from the loader 40 to the unloader 70 and the transport means is of a construction that enables continuous cleaning to be realized. With the transport means of the conveyor type adopted, an accommodating container for semiconductor wafers and constituents thereof in irregular shapes can be cleaned continuously and simultaneously.

The transport stage 80 of the conveyor type is of a construction that can cause the member T to be cleaned to continuously flow from the loader 40 to the unloader 70, while it may be of a construction that is partitioned into plural blocks. The construction includes a transport part in the shape of a belt where plural long narrow belts 80a each in the shape of a ring, which is made from a synthetic resin such as polyurethane, a synthetic rubber or the like, are arranged at intervals each of several centimeters, and wound around many of rollers 81, wherein the long narrow belts 80a in the shape of a ring type are rotated by a driving section such as a motor through a gear box not shown; thereby enabling the member T to be cleaned in a state being placed on the belts 80a to be transported.

The cleaning section 50 is a cleaning apparatus including, for example, as shown in FIGS. 5 to 10, a jet mechanism for jetting a mist-like cleaning liquid with a high pressure through plural nozzles 52a, 54a and 56a. In the embodiment, the nozzles 52a, 54a and 56a are disposed in directions upward and downward. No specific limitation is imposed on an arrangement of the nozzles 52a, 54a and 56a and the nozzles 52a, 54a and 56a may be arranged only on the sides of the member T to be cleaned or may be arranged on the sides of and above and below the member T to be cleaned. The high cleaning effect is obtained in a case where a cleaning liquid is jetted from above and from below and only the arrangement in which the nozzles are located above and below the member T to be cleaned as in the embodiment exerts a sufficient effect.

A mist-like cleaning solution is jetted as particles with sizes 100 μm or less from the nozzles 52a, 54a and 56a under a pressure of the order of 0.3 MPa (of the order in the range of from 0.2 to 0.4 MPa). With such a construction adopted, even very small particles can be removed and even a member T to be cleaned in a complex shape is cleaned with very high cleanliness. The mist-like cleaning liquid is jetted in a mixture of a gas (air or nitrogen) and a liquid (a cleaning liquid) formed in portions of the nozzles 52a, 54a and 56a. By jetting the mixture, the cleaning liquid is transformed into a fine mist, which is a preferable state for cleaning.

Incidentally, a particle size of a mist is a value measured with a Phase Doppler Particle Analyzer. The particle size can be varied by adjusting a size of a hole formed at the tip of a nozzle and a balance between a pressure of an introduced gas (air or nitrogen) and a pressure of a liquid. The pressure is a supply pressure of air or nitrogen, which is measured with a pressure gage.

In a preferred embodiment of the cleaning system 30 of the present invention, plural cleaning sections 50 for cleaning with a mist-like cleaning liquid L are arranged as shown in FIG. 1. Especially, the cleaning section 50 includes: a precleaning section 52 with pure water L1; a cleaning section 54 with a chemical solution L2; and a rinse section 56 with pure water. The rinse section 56 is further divided into three parts in the embodiment.

The cleaning liquids L1 and L2 are different according to a purpose, but at least pure water cleaning is performed. In the wafer accommodating container 12 that is used for storage of semiconductor wafers W, a cleaning liquid added with surfactant is used to thereby improve wettability of the container, so that all the corners of the container are cleaned. In the consecutive cleaning system 30 as shown in FIG. 1, cleaning with pure water L1 is conducted in the precleaning section 52, the chemical solution L2 of pure water added with surfactant is used in the cleaning section 54 and cleaning with pure water with high purity L1 is again conducted in the rinse section 56 as the last section.

On this occasion, in the cleaning system 30, as described later, the cleaning liquid (pure water) L1 supplied in the precleaning section 52 is of the cleaning liquid (pure water) L1 used in the rinse section 56 according to a circulation system. With such a construction adopted, effective utilization of pure water is realized.

In FIG. 1, a reference 82 designates a drain collecting tank provided below the transport stage 80. The drain collecting tank 82 is partitioned into a first collecting section 82a located below the loader section 40 and the precleaning section 52; a second collecting section 82b located below the chemical solution cleaning section 54; a third collecting section 82c located below the rinse section 56; and a fourth collecting section 82d located below the drying section 60 and the unloader section 70.

The first collecting section 82a is connected to a main drain pipe 86 through a first drain pipe 84a, and first collected water that is collected in the first collecting section 82a from the loader section 40 and the precleaning section 52 is removed as a drain D from the main drain pipe 86 through a drain line.

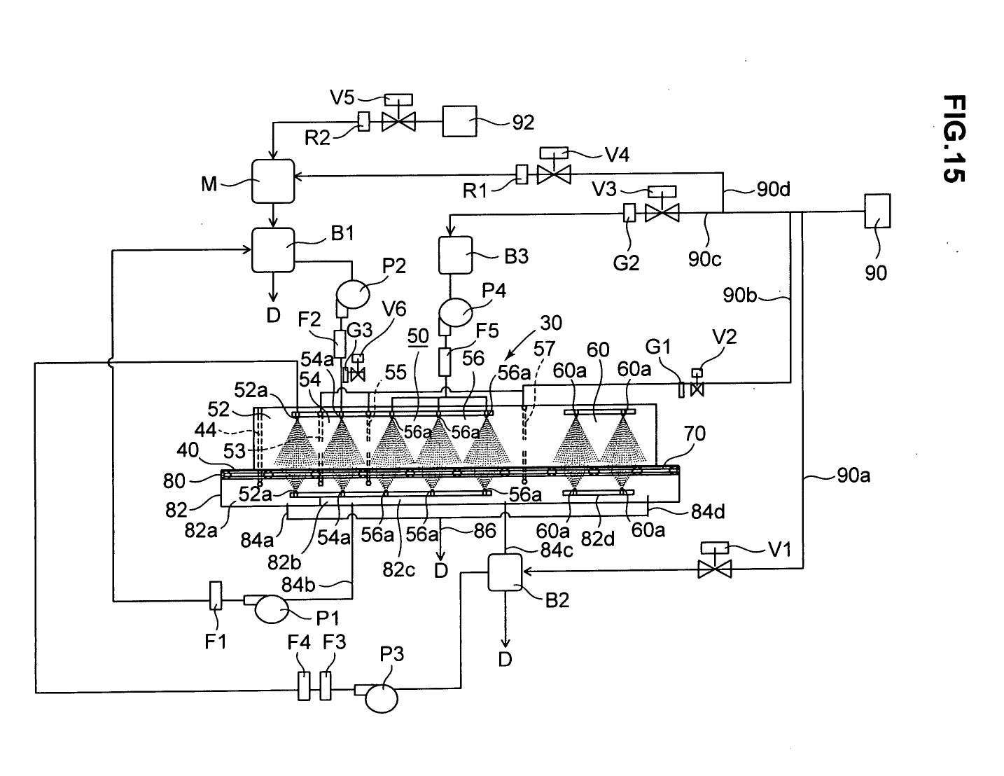

The second collecting section 82b is connected to a first circulation pipe 84b, and second collected water (a chemical solution) that is collected in the second collecting section 82b from the chemical solution cleaning section 54 is recycled as a chemical solution that is clarified with being passed through a pump P1, a filter F1, a buffer tank B1, a pump 2 and a filter F2, as shown later in FIG. 15.

The third collecting section 82c is connected to a second circulation pipe 84c, and third collecting water (pure water) that is collected in the third collecting section 82c from the rinse section 56 is recycled as pure water for the precleaning section 52 that is purified with being passed through a buffer tank B2, a pump P3, and filters F3 and F4, as shown later in FIG. 15.

The fourth collecting section 82d is connected to the main drain pipe 86 through a second drain pipe 84d, and fourth collected wafer that is collected in the fourth collecting section 82d from the drying section 60 and the unloader section 70 is removed as a drain D from the main drain pipe 86 through a drain line.

FIG. 15 is a schematic explanatory view showing a supply flow of cleaning liquids in the cleaning system of the present invention. In FIG. 15, a reference 90 designates a pure wafer supply apparatus, which is connected to precleaning section piping 90a, water curtain piping 90b, rinse section piping 90c, and chemical solution cleaning section piping 90d, respectively.

Pure water supplied to the precleaning section piping 90a from the pure water supply apparatus 90 is further supplied to a buffer tank B2 through a valve V1. The above-mentioned third collected water (pure water) from the rinse section 56 is supplied to the buffer tank B2 through a second circulation pipe 84c. Fresh pure water and the collected pure water are mixed together in the buffer tank B2, and the mixed pure water is purified by being passed through the pump P3 and the filters F3 and F4 to be supplied as a cleaning liquid (pure water) for a nozzle 52a of the precleaning section 52a. If pure water is excessively supplied to the buffer tank B2, the excessive pure water overflows and is removed as a drain D.

The pure water supplied into the water curtain piping 90b from the pure water supply apparatus 90 is supplied to water curtains 53, 55 and 57 through the valve V2 and the flowmeter G1.

Pure water supplied to the rinse piping 90c from the pure water supply apparatus 90 is supplied to a nozzle 56a of the rinse section 56 as a cleaning liquid (pure water) through the valve V3, the flowmeter G2, the buffer tank G3, the pump P4 and the filter F5.

Pure wafer supplied to the chemical solution cleaning piping 90d from the pure water supply apparatus is supplied to a mixing tank M through the valve V4 and a weighting sensor R1. Surfactant is also supplied to the mixing tank M from a surfactant supply apparatus 92 through the valve 5 and the weighing sensor R2. A chemical solution constituted of pure water and surfactant with any concentration thereof is prepared in the mixing tank M and the prepared chemical solution is sent to the buffer tank B1. The second collected water (chemical solution) from the chemical solution cleaning section 54 is, as described above, supplied to the buffer tank B1 through the first circulation pipe 84b, the pump P1 and the filter F1. A fresh chemical solution and the collected chemical solution are mixed together in the buffer tank B1 and the mixture is supplied as a cleaning liquid (chemical solution) for the nozzle 54a of the chemical cleaning section 54 through the pump P2, the filter F2 and the flowmeter G3. If the chemical solution is excessively supplied to the buffer tank B1, the excessive chemical solution overflows and is removed as a drain D.

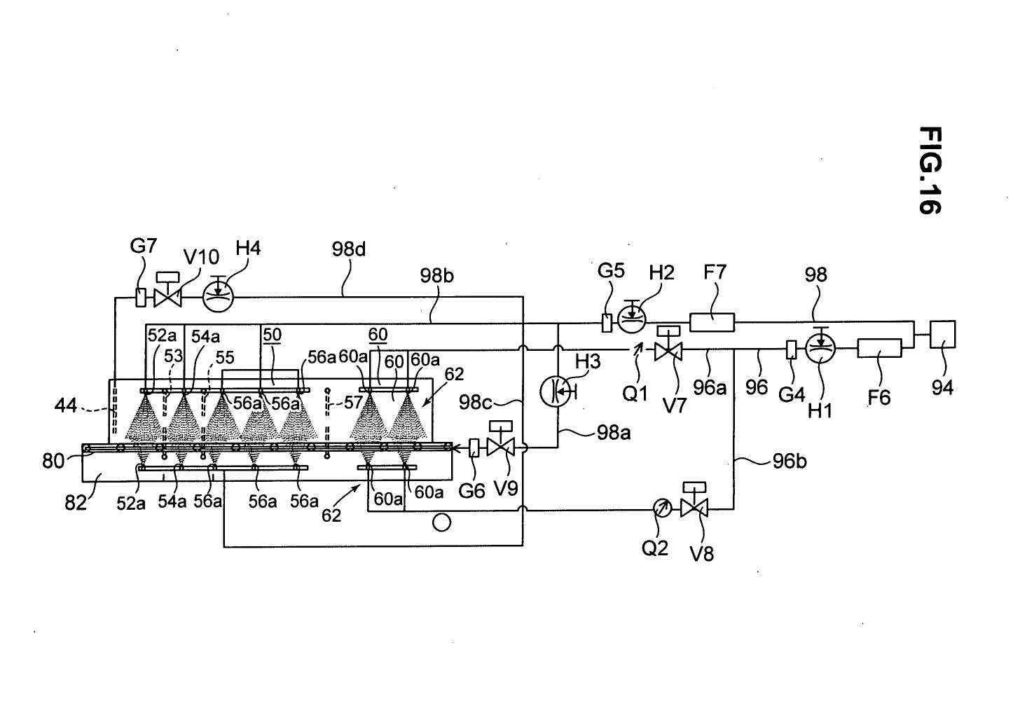

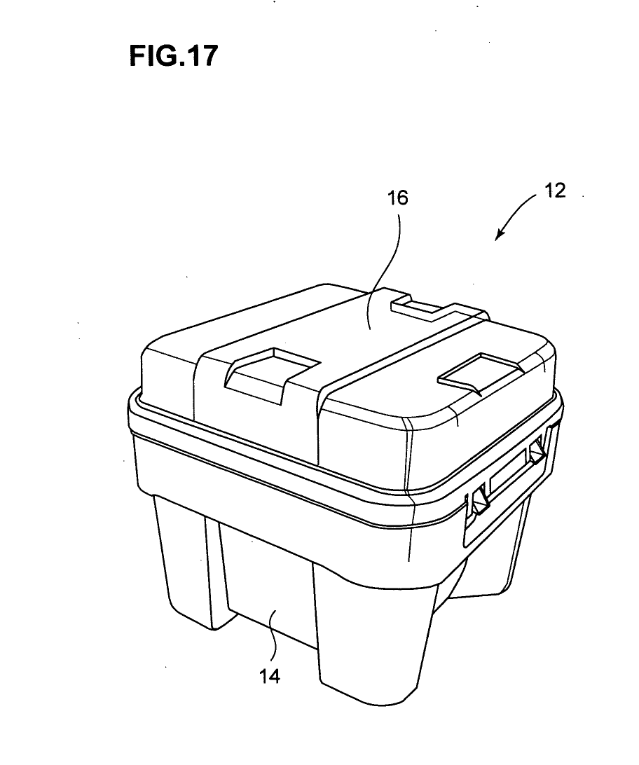

FIG. 16 is a schematic explanatory view showing a supply flow of air in the cleaning system of the present invention. In FIG. 16, a reference 94 designates an air supply apparatus, which is connected to drying section piping 96 and nozzle piping 98, respectively. The drying piping 96 is branched in two ways so as to have upper drying section piping 96a and lower drying section piping 96b. The nozzle piping 98 is branched in four ways so as to have gear box purge piping 98a, upper nozzle piping 98b, lower nozzle piping 98c and air curtain piping 98d.

Air supplied from the air supply apparatus 94 to the drying section piping 96 is introduced into the upper drying section piping 96a and the lower drying section piping 96b through a filter F6, a regulator H1 and a flowmeter G4. The air introduced into the upper drying section piping 96a is supplied to air nozzles 60a on the upper side through a valve V7 and a pressure gage Q1 and jetted from the nozzles 60a to act as an air cutter 62. On the other hand, the air introduced into the lower drying section piping 96b is supplied to the air nozzles 60a on the lower side through a valve 8 and a pressure gage Q2 and jetted from the nozzles 60a to act as an air cutter 62.

Air supplied from the air supply apparatus 94 to the nozzle piping 98 is introduced, through a filter F7 and a regulator H2, into the gear box purge piping 98a, the upper nozzle piping 98b, the lower nozzle piping 98c and the air curtain piping 98d.

Air introduced into the gear box purge piping 98a is supplied into a gear box not shown for driving a long ring-like narrow belt 80a on the transport stage 80 through a regulator H3, a valve V9 and a flowmeter G6, air-purges the interior of the gear box and eventually is exhausted.

Air introduced into the upper and lower nozzle piping 98b and 98c is supplied into the nozzles 52a, 54a and 56a, and jetted under a high pressure together with a cleaning liquid supplied by the supply flow shown in FIG. 15.

Air introduced into the air curtain piping 98d is jetted through a regulator H4, a valve V10 and a flow meter G7 to form an air curtain 44.

More of description will be given of constituents of a cleaning system 30 of the present invention. FIGS. 2 to 4 are explanatory views describing an outline of the loader section 40. In the loader section 40, a member T to be cleaned is set on the transport stage 80 such as a conveyor. On this occasion, a positioning guide 42 positionally controls the member T to be cleaned before it is introduced into the cleaning section 50. In a case where the member T to be cleaned is concave as a container accommodating wafers, the member T is positioned such that the opening portion thereof is downward. The air curtain 44 is provided at the entrance of the cleaning section 50 from the loader 40. The air curtain 44 functions to prevent waterdrops whirled up in the interior of the tunnel-like outer wall 51 provided in the cleaning section 50 from flying out to the outside. The amount of flowing air in the air curtain 44 is controllable. Incidentally, a reference 46 designates an exhaust pipe provided below the air curtain 44.

Then, description will be given of the precleaning section 52. FIGS. 5 and 6 are schematic explanatory views showing the precleaning section 52. In the precleaning section 52, there is installed the nozzle 52a, which is a jet mechanism for jetting the mist-like cleaning liquid L1 under a high pressure in the tunnel-like outer wall 51. The tunnel-like outer wall 51 is formed with a rounded shape such that waterdrops attached on the inner wall thereof flow down smoothly along the surface thereof.

No specific limitation is placed on the number and position of the nozzle 52a and these may be set in accordance with a size of the member T to be cleaned, a moving rate of the transport stage 80 such as a conveyor (a moving rate of the member T to be cleaned) and the like. By this setting, the cleaning tact time can be adjusted.

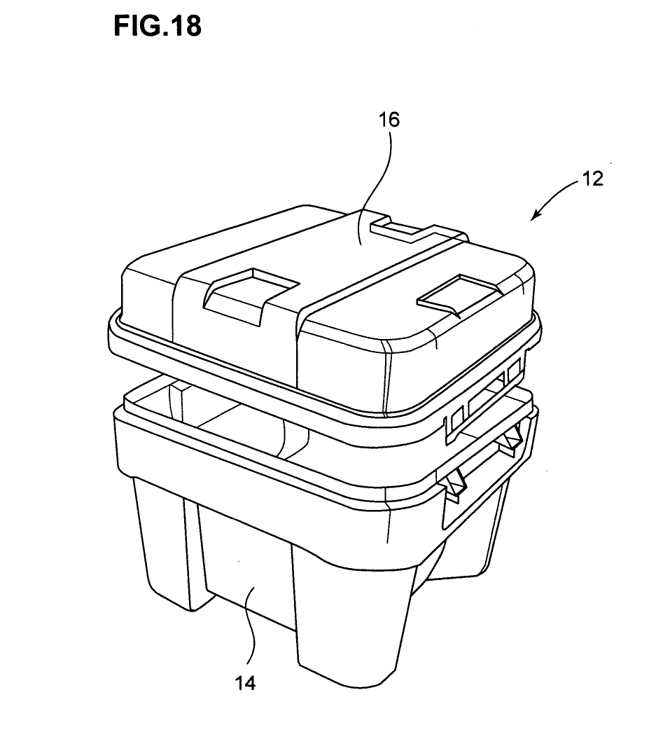

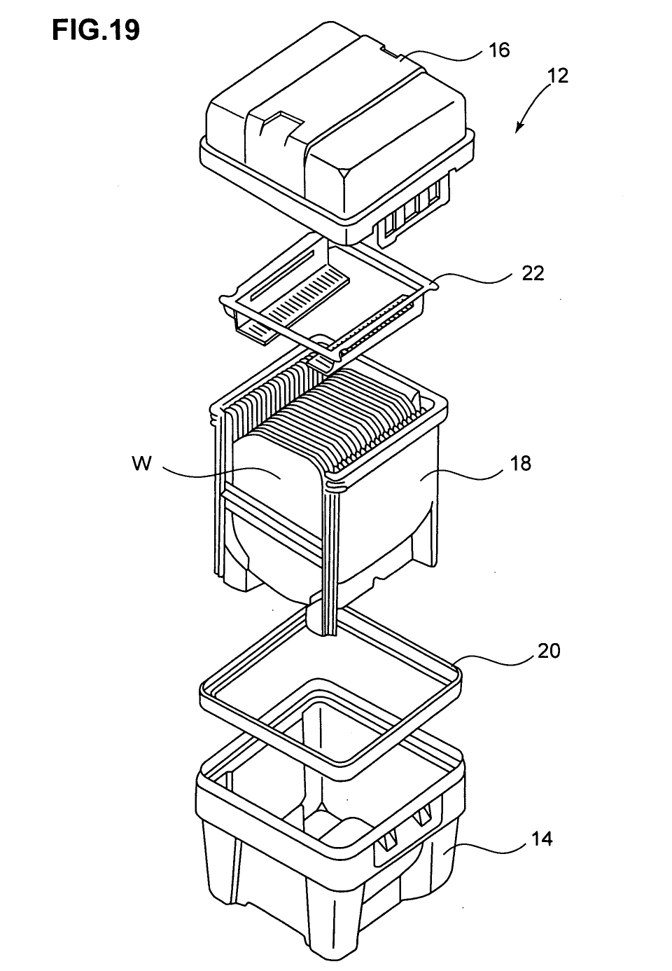

In FIGS. 5 and 6, in a case of, for example, a cleaning system for cleaning the accommodating container 12 for silicon wafers with a diameter of 200 mm as shown in FIGS. 17 to 19, one group of the nine nozzles 52a for jetting a cleaning liquid downward are installed on the upper side in arrangement of 3 columns in the moving direction of the member T to be cleaned and 3 rows in the direction normal thereto, while another group of the nine nozzles 52a for jetting a cleaning liquid upward are installed on the lower side in the same arrangement described above. Hence, a total number of the installed nozzles 52a is 18. When the above mentioned arrangement of the number of the nozzles 52a is provided, a cleaning rate can be increased and in the embodiment of FIGS. 5 and 6, sufficient cleaning is secured even if the passing through rate of the member T to be cleaned in the precleaning section 52 is on the order of 3 sec.

The nozzle 52a used in the precleaning section 52 is a nozzle that can mix and jet a gas (air) and a liquid (pure water) supplied in the supply systems as shown in FIGS. 15 and 16, and are preferably made from resin. Though a metal nozzle can be used, it is preferable to use a nozzle made from material (resin) less in contamination since metal contamination is an important issue in addition to particle contamination in a case where an accommodating container for silicon wafers used in the semiconductor field.

A cleaning liquid used in the precleaning section 52 may be pure water. The cleaning liquid may be pure water supplied from the pure water supply apparatus 90, but in the cleaning system of the present invention, pure water used already in the rinse section 56 described later is reused in the form of recycling. That is, as shown in FIG. 15, pure water used already in the rinse section is accumulated in a buffer tank B2 and then recycled by passing it through the pump P3 and the filters F3 and F4. The filters may be installed, for example, in the form of plural stages including a filter capable of removing foreign matter of a size of the order of 2 μm and another filter capable of removing foreign matter of a size of the order of 0.1 μm. With such filters adopted, the pure water can be purified to pure water having a level usable in the precleaning section 52 without a problem.

A flow rate of pure water and a flow rate of air supplied from the gas supply system are adjusted and mixed together in the nozzles 52a, so that the cleaning liquid is jetted in a mist state. For example, air (with a supply pressure of about 0.1 MPa) and the above-mentioned pure water (with a liquid pressure of about 0.2 MPa) are mixed together and then the cleaning liquid is jetted onto the member T to be cleaned in a mist state. With such a construction adopted, a pressure of the jetted mist-like cleaning liquid L1 is set to a value in the range of from 0.2 to 0.4 MPa. Incidentally, for example, two-fluid fine mist forming nozzles manufactured by H. Ikeuchi. & Co., Ltd. can be effectively used as the nozzle 52a.

Besides, the water curtain 53 is provided after the precleaning 52. With the water curtain 53 adopted, very small size waterdrops attached to the member T to be cleaned are removed. The water curtain 53 prevent the chemical solution of the next section from mixing into the precleaning section 52 to thereby separate the sections from each other.

Then, description will be given of the cleaning section 54 with the chemical liquid L2 using FIGS. 7 and 8. The basic construction of the chemical solution cleaning section 54 is the same as the precleaning section 52 and the number and an arrangement of nozzle 54a, which is a jet mechanism in the chemical solution cleaning section 54, is the same as in the precleaning section 52. The chemical solution cleaning section 54 is different from the precleaning section 52 only in terms of the cleaning liquid to be supplied. In the chemical solution cleaning section, there is used the chemical solution L2 constituted of pure water added with surfactant. No specific limitation is placed on the surfactant to be added, while there is preferably usable surfactant less in foamability, such as SCOUROL (a trade name of nonionic surfactant manufactured by Kao Corporation). It is preferable that the concentration thereof is preferably in the range of from 0.001 to 0.01%. As in the precleaning section 52, the chemical solution is mixed with air to be jetted to the member T to be cleaned in a mist manner.

The chemical solution L2 constituted of pure water added with the surfactant is supplied in a circulation system for recycling. For example, as described already using FIG. 15, at first, the surfactant from the surfactant supply apparatus 92 and the pure water from the pure water supply apparatus 90 are mixed in the mixing tank M to prepare a fresh chemical solution with an adjusted concentration, the fresh chemical solution is sent to the buffer tank B1 and further supplied to the nozzle 54a of the chemical solution cleaning section 54 through the pump P2 and the filter F2. The used chemical solution is recovered to return to the buffer tank B1.

There is disposed a water curtain 55 between the chemical solution cleaning solution 54 and the rinse section 56 subsequent thereto. In the embodiment shown in the figure, it is designed such that the member T to be cleaned passes through the chemical solution cleaning section 54 in about 3 sec.

Then, description will be given of the rinse section 56 using FIGS. 9 and 10. A basic construction for cleaning in the rinse section 56 is the same as in the precleaning section 52 and the chemical solution cleaning section 54. The rinse section 56 is different from the precleaning section 52 and the chemical solution cleaning section 54 in terms of, for example, the number of the nozzle 56a disposed therein. The rinse section 56 is a final cleaning line, wherein the surfactant attached to the member T to be cleaned is necessarily removed. In the embodiment shown in the figure, total 27 nozzles are installed on the upper side in arrangement of 9 columns in the moving direction of the member T to be cleaned and 3 rows in a direction normal thereto, and total 27 nozzles are installed on the lower side in the same arrangement described above so that the chemical solution is jetted from upward and downward. It is designed such that the member T to be cleaned passes through the cleaning section 52 in a time thrice as long as that in the precleaning section 52 or the chemical solution cleaning section 54. That is, it is designed in the embodiment shown in the figure such that the member T passes through the rinse section in a time of the order of 9 sec.

The pure water to be used here is fresh pure water directly supplied from the pure water supply apparatus 90. Also, the pure water to be used here is recycled because a great quantity of pure water is used here. As described above, for the recycling purpose, the pure water used here may be circulated to the precleaning section 52.

Besides, a construction adopted in the embodiment is equipped with the drying section 60, where a liquid attached to the member T to be cleaned is removed by air A, installed after the member T to be cleaned passes through the cleaning section 50. The drying section 60 is, as shown in FIGS. 11 and 12, equipped with an air cutter 62 for jetting air and the air cutter 62 swings to remove waterdrops on the member T to be cleaned. The air cutter 62 is constituted of plural air nozzles 60a each having a slit or plural small holes and blows away waterdrops with air at a high pressure (on the order in the range of from 0.2 to 0.4 MPa). Incidentally, a reference 64 designates an exhaust pipe provided below the air cutter 62.

In this case, a water curtain 57 is provided at the boundary between the cleaning section 50 and the drying section 60. With such a construction adopted, mist-like waterdrops attached to the member T to be cleaned in cleaning are removed and the remaining waterdrops have comparative large sizes; therefore it becomes easy to dry the member T by air. It is not necessary to perfectly dry the member T in the drying section 60, and the member T may be perfectly dried in the next step.

The member T to be cleaned having been cleaned this way are discharged to the unloader section 70. The unloader 70 is of a construction in which a member T to be cleaned is, for example, as shown in FIGS. 13 and 14, placed on a working table 88 in a clean unit 87. The clean unit 87 is not especially necessary to be integrated with the cleaning system 30 into one body. The unloader 70 may be continuously connected to the drying step subsequent thereto. Incidentally, if a charge remover or the like is installed in the unloader 70, particles are preferably not reattached to the member T to be cleaned having been cleaned. With such an integrated cleaning system adopted, there is ensured cleaning excellent in cleaning capability and good in efficiency.

More concrete description will be described using empirical examples and examples, and it is needless to say that it should be understood that the empirical examples and the examples are presented by way of illustration only and not to be construed by way of limitation.

### EMPIRICAL EXAMPLE 1

Experiments here were conducted in order to confirm a removing capability of particles on a conventional dipping method, a conventional shower method and the high pressure spraying method of the present invention. Comparison on particle removing capability in the same condition is difficult between particle removing methods that are different in principle of removing particles from one another; therefore, in the experiments, especially in order to confirm the removing capability for very small size particles, overall cleaning conditions were determined in three methods including the conventional dipping method, the conventional shower method and the high pressure spraying method of the present invention so that particles with a size of 0.5 μm or more were at the same level (5 particles or less), and comparison was performed on the removing capability (the cleaning capability) of particles with a size of 0.5 μm or less. Cleaning by the three methods using a cleaning liquid containing surfactant at a concentration of 0.01% was conducted only in the chemical solution cleaning section, and other steps including precleaning, rinse and drying were performed in a similar method, respectively. Especially in the empirical example, precleaning and rinsing were conducted using a shower method, respectively.

The dipping method was conducted in the order of procedure described below: pure water shower cleaning (3 sec)—dipping in a surfactant bath (3 sec)—pure water shower rinse (15 sec). The shower method was conducted in the order of procedure described below: pure water shower cleaning (3 sec)—shower cleaning with surfactant (3 sec)—pure water shower rinse (15 sec). Droplet sizes in the shower were on the order in the range of from 0.5 to 1.0 mm.

The high pressure spraying method of the present invention was conducted in the order of procedure described below: pure water shower cleaning (3 sec)—high pressure spraying cleaning with surfactant (3 sec)—pure water shower rinse (15 sec). Droplet sizes in the spraying were on the order in the range of from 10 to 100 μm.

In the cleaning procedure containing the dipping method, plural wafer accommodating containers were cleaned with the result that in a case where the number of particles with 0.5 μm or more in size was 5.0 counts on the average, the number of particles with 0.3 μm or more in size was 19.5 counts on the average, the number of particles with 0.2 μm or more was 164.4 counts on the average, and the number of particles with 0.1 μm or more in size was 2628.8 counts on the average.

In the shower method, plural wafer accommodating containers were cleaned with the result that in a case where the number of particles with 0.5 μm or more in size was 4.2 counts on the average, the number of particles with 0.3 μm or more in size was 15.3 counts on the average, the number of particles with 0.2 μm or more in size was 121.5 counts on the average and the number of particles with 0.1 μm or more in size was 2060.0 counts on the average.

In the cleaning procedure containing the high pressure spraying method of the present invention, plural wafer accommodating containers were cleaned with the result that in a case where the number of particles with 0.5 μm or more in size was 4.4 counts on the average, the number of particles with 0.3 μm or more in size was 12.4 counts on the average, the number of particles with 0.2 μm or more in size was 71.2 counts on the average, and the number of particles with 0.1 μm or more in size was 909.6 counts on the average.

It is understood that in a case where the method of the present invention was employed in this way, particles with a size of the order of 0.1 μm and 0.2 μm are especially removed effectively.

### EXAMPLE 1

An example was shown in which the cleaning system shown in FIGS. 1 to 16 was employed and there was cleaned a polycarbonate wafer accommodating container, as shown in FIGS. 17 to 19, capable of accommodating 25 silicon wafers each with a diameter of 200 mm used in the semiconductor field. The accommodating container is constituted of a cover, a substrate presser (a retainer), a substrate accommodating cassette (an inner cassette), a packing (a gasket), and a container body (a lower box), which are necessarily cleaned. Incidentally, in the cleaning system of the present invention, the retainer and the gasket can be individually cleaned, while in this example, plural pieces are collectively put into a basket, transported and cleaned.

In this example, the cover and the container body that constitute the accommodating container and are in the concave shape are set on the loader section of the cleaning system each in a state of facing an opening thereof downward. The above pieces were passed through the air curtain jetted at a pressure of the order in the range of from about 0.1 to about 0.2 PMa and thereafter moved into the precleaning section.

In the precleaning section, mist-like pure water (reuse of pure water having been used in the rinse section) with the particle size in the range of from 10 to 100 μm was supplied at a pressure of 0.3 MPa. As the nozzles there were employed two-liquid fine mist forming nozzles manufactured by H. Ikeuchi. & Co., Ltd. (BIM-PR V type) and 9 nozzles were disposed on the upper and lower sides, respectively (18 nozzles in total), which are described in the embodiment. The moving rate of the conveyor was adjusted so that the pieces can pass through this stage in 3 sec.

Then, the pieces were passed through the water curtain in a state of a water shower from holes each with a diameter of 1 mm and pure water containing surfactant (SCOUROL) of 0.01% was supplied in a mist state with the particle size in the range of from 10 to 100 μm at a pressure of 0.3 MPa in a similar way in the precleaing section. It was also set for the pieces to pass through this stage in 3 sec.

Thereafter, the pieces passed through the water curtain and moved into the rinse section. In the rinse section, cleaning was conducted in the manner that the number of the nozzles was increased to a value thrice as many as the precleaning section and a length of the conveyor in this section was increased to a value thrice as long as the precleaning section. Hence, it was set for the pieces to pass through this stage in 9 sec. A cleaning liquid in this area was pure water, which was supplied in a mist state with the particle size in the range of from 10 to 100 μm at a pressure of 0.3 MPa.

Thereafter, the pieces passed through the water curtain and moved into the drying section. The drying section of the cleaning system of the present invention, however, has a main purpose of draining and hence the pieces are no perfectly dried in this drying section (the perfect drying may also be achieved) because the pieces are dried in a separate later step. In the drying section, the air cutter removes the waterdrops attached to the pieces. The air cutter has a construction in which plural nozzles with plural holes in the shape of a slit or a circle of a diameter of the order of 1 mm are arranged and dry air (the air is high in cleanliness by being passed through a filter) is blown to the pieces at a pressure in the range of from 0.2 to 0.3 MPa so as to remove the droplets. Thereafter, the pieces were moved to the unloader section to finish the cleaning.

The pieces of the accommodating container having come out after passing through the above-mentioned cleaning system were assembled after natural drying in a clean bench to complete the accommodating container and thereafter, the number of particles in the accommodating container was counted. Counting the particles was performed in such a way that pure water was put into the cleaned container, the container was shaken for several minutes and allowed to stand for a predetermined time, and thereafter particles in the liquid were counted with a liquid particle counter.

As a result, particles with 0.3 μm or more in size were 27.7 counts on the average and particles with 0.5 μm or more in size were 3.8 counts on the average, from which it was found that the particle level was very excellent and therefore the cleaning system had a sufficiently high cleaning effect. Besides, the cleaning time was about 20 sec and operation efficiency was high.

### COMPARATIVE EXAMPLE 1

The same chemical solution as in Example 1 was used and the cleaning was manually conducted all in the dipping method. That is, an accommodating container was dipped into the pure water bath as precleaning, then further dipped into a water bath to which surfactant was added, and thereafter, the three rinse baths containing pure water were installed and cleaning was conducted. The cleaning time of each bath was on the order of 10 sec. Thereafter water attached to the container was drained off and dried in a clean bench.

Particles in the accommodating container cleaned in the dipping method were measured in the same way as in Example 1 with the result that particles with 0.3 μm or more in size were 459 counts on the average and particles with 0.5 μm or more in size were 107 counts on the average, the particles being many. It was found that a sufficient cleaning effect was not obtained. If the cleaning time is longer even in the dipping method, a removing ability for particles with some size is improved, but the cleaning effect is degraded to that extent. Besides, very small particles cannot necessarily be removed even in a longer cleaning time, which leads to the limitation of this method.

Even if brush cleaning, supersonic cleaning or the like was added to the construction of Comparative Example 1, the number of particles with 0.3 μm or more in size was on the order in the range of from 50 to 500 counts, which showed no improvement on the cleaning effect.

The present invention is not limited to the embodiments and the embodiments are presented by way of illustration only and any of modifications or alterations thereof each having substantially the same construction and exerting similar functions and results as in the technical concept in meets and bounds of the claims of the present invention are included in the technical scope of the present invention.

For example, while it is preferable that the cleaning system has the above-mentioned drying section for draining, because of easiness of the following processing, another construction may be adopted in which no drying section is provided in the system (without conducting drying with an air knife) and drying is separately conducted in a clean bench or a dryer of an oven type. To the contrary, in the drying section, the purpose thereof resides in draining and perfect drying was not conducted therein, but a system may be adopted in which perfect drying may be completed in this drying section. It is not necessary to limit the drying section to the above-mentioned construction. If an environment can be maintained so as not to increase the smaller number of particles as a result of the cleaning due to reattachment and the like, no specific limitation is placed on the drying method.

Besides, it is not necessarily required to employ a cleaning liquid containing surfactant and the like. When an accommodating container is comparatively contaminated, by adding surfactant to a cleaning liquid, there are improved the wettability thereof and the removing ability for particles or the like, whereas when a new accommodating container or the like is cleaned, a comparatively good particle level can be ensured by cleaning only with pure water. It is understood that for the purpose of removing particles the cleaning liquid is very effectively supplied in a mist at a high pressure. While in the embodiments and examples, description has been given of a wafer accommodating container capable of accommodating silicon wafers each with a diameter of 200 mm, especially a container for shipment of wafers shown in FIGS. 17 to 19, as an example, a member T to be cleaned is not limited to this, and the cleaning can be applied to a container accommodating wafers each with a diameter of 300 mm, a container called as a carrier used in a process or the like.

Capability of Exploitation in Industry:

According to the present invention, as described above, particles each with very small particle diameter of the order of 0.3 μm, which are attached to a container and which is problematic in the semiconductor field, can be sufficiently cleaned and removed.

According to the present invention, a sufficient cleaning effect is obtained on a bottom face and a side face of each of grooves regardless of a shape of an accommodating container, for example, regardless of a depth or a width of each of grooves.

According to the present invention, considerably small particles can be removed without using brush cleaning, supersonic cleaning or a chemical liquid such as organic solvent, which results in simplification of a cleaning line and reduction in cost of the chemical liquid.

In the cleaning system of the present invention, a time from loading of an accommodating container to unloading thereof is short, efficient cleaning is assured and full automation can be implemented.

1. A cleaning apparatus for cleaning a member used in the semiconductor field comprising:
one nozzle or plural nozzles; and
a jet mechanism for jetting a mist-like cleaning liquid with a high pressure from the one nozzle or the plural nozzles to the member to be cleaned.

2. The cleaning apparatus according to claim 1, wherein the member is cleaned with the nozzles disposed in directions upward and downward.

3. The cleaning apparatus according to claim 1, wherein particle size of the jetted mist-like cleaning liquid is 100 μm or less.

4. The cleaning apparatus according to claim 1, wherein a pressure of the jetted mist-like cleaning liquid is in the range of from 0.2 to 0.4 MPa.

5. The cleaning apparatus according to claim 1, wherein the mist-like cleaning liquid is jetted in such a way that a gas is mixed into the cleaning liquid in a liquid state.

6. The cleaning apparatus according to claim 1, wherein the cleaning liquid is pure water added with surfactant.

7. The cleaning apparatus according to claim 1, wherein the cleaning liquid is pure water.

8. A cleaning system for cleaning a member used in the semiconductor field comprising: a loader section for setting the member to be cleaned; an unloader section for collecting the member; and a transport stage for continuously transporting the member from the loader section to the unloader section, wherein a cleaning section for cleaning the member with a mist-like cleaning liquid is provided on the transport stage.

9. The cleaning system according to claim 8, wherein the cleaning section has an outer wall in the shape of a tunnel.

10. A cleaning system, wherein the cleaning section is constituted of the cleaning apparatus according to claim 1.

11. The cleaning system according to claim 8, wherein a transport stage for continuously transporting the member to be cleaned from the loader section to the unloader section is a conveyor type transport apparatus.

12. The cleaning system according to claim 8, wherein an air curtain is provided between the loader section and the cleaning section.

13. The cleaning system according to claim 8, wherein plural cleaning sections for cleaning the members with the mist-like cleaning liquid are consecutively disposed.

14. The cleaning system according to claim 13, wherein the plural cleaning sections include at least a precleaning section for cleaning the member with pure water, a chemical solution cleaning section for cleaning the member with a chemical solution, and a rinse section.

15. The cleaning system according to claim 14, wherein as the cleaning liquid supplied in the precleaning section, the cleaning liquid used in the rinse section is used.

16. The cleaning system according to claim 8, wherein a water curtain is provided after the cleaning section.

17. The cleaning system according to claim 8, wherein a drying section removing a liquid attached to the member to be cleaned by air is installed after the member passes through the cleaning section.

18. A cleaning method cleaning a member used in the semiconductor field, wherein a cleaning liquid with a small mist particle size is blown to a member to be cleaned under a high pressure to thereby clean the member.

19. The cleaning method according to claim 18, wherein the particle size of the mist-like cleaning liquid having small particle size is 100 μm or less.

20. The cleaning method according to claim 18, wherein a pressure under which the mist-like cleaning liquid having small particle size is blown is in the range of from 0.2 to 0.4 MPa.

21. The cleaning method according to claim 18, wherein the member to be cleaned is a wafer accommodating container for accommodating semiconductor wafers.

22. The cleaning method according to claim 18, wherein particles with a size of 0.5 μm or less attached to the member to be cleaned are removed.

23. The cleaning method according to claim 18, wherein with the cleaning system according to claim 8, the member is transported by the transport stage, and is cleaned in the cleaning section.
